(19) United States
(12) Patent Application Publication
(10) Pub. No.: US 2010/0224948 A1
(43) Pub. Date: Sep. 9, 2010

(54) SOLID-STATE IMAGING ELEMENT, METHOD FOR FABRICATING THE SAME, AND SOLID-STATE IMAGING DEVICE

(75) Inventors: Yasuo TAKEUCHI, Osaka (JP); Tomoko Komatsu, Kyoto (JP); Masashi Kuroda, Kyoto (JP); Tetsushi Nishio, Kyoto (JP); Kiyokazu Itoi, Kyoto (JP)

Correspondence Address: MCDERMOTT WILL & EMERY LLP, 600 13TH STREET, NW, WASHINGTON, DC, 20005-3096, US

(73) Assignee: PANASONIC CORPORATION, Osaka (JP)

(21) Appl. No.: 12/783,086

(22) Filed: May 19, 2010

Related U.S. Application Data
(63) Continuation of application No. PCT/JP2009/002259, filed on Jul. 3, 2008.

(30) Foreign Application Priority Data
Jul. 3, 2008 (JP) 2008-174660

(51) Int. Cl. H01L 31/0232; H01L 31/18; H01L 31/0216

(52) U.S. Cl. 257/432; 438/69; 257/E31.127; 257/E31.121

(57) ABSTRACT

A solid-state imaging element includes a semiconductor substrate formed with a valid pixel section including a plurality of photodetector sections, spacers formed on the valid pixel section, a transparent adhesive filling gaps among the spacers, and a transparent substrate which is bonded onto the spacers using the transparent adhesive and covers the valid pixel section when viewed in plan. Electrode pad sections are formed in a region of the semiconductor substrate located outside the valid pixel section.

### CROSS-REFERENCE TO RELATED APPLICATION

This is a continuation of PCT International Application PCT/JP2009/002259 filed on May 21, 2009, which claims priority to Japanese Patent Application No. 2008-174660 filed on Jul. 3, 2008. The disclosures of these applications including the specifications, the drawings, and the claims are hereby incorporated by reference in its entirety.

### BACKGROUND

The technique disclosed herein relates to solid-state imaging elements for use in digital cameras, etc., methods for fabricating the same, and solid-state imaging devices equipped with the solid-state imaging elements.

In the field of solid-state imaging devices, extensive research and development have been directed at improving the sensitivities of solid-state imaging devices. Japanese Patent Publication No. H02-2675 describes a technique in which the sensitivity of a solid-state imaging device is improved by reducing the parasitic capacitance of a floating diffusion region thereof. A typical solid-state imaging device is configured so that a photodetector section and a floating diffusion region are formed in a semiconductor substrate so as to be spaced from each other. The semiconductor substrate is covered with an organic film for passivation. In Japanese Patent Publication No. H02-2675, a portion of this organic film covering the floating diffusion region is removed. This reduces the parasitic capacitance of the floating diffusion region. This reduction improves the voltage conversion efficiency of the floating diffusion region. As a result, the sensitivity of a solid-state imaging device can be improved.

Instead of a hollow package structure which has been frequently used, a transparent-substrate-directly-bonded package structure has been proposed as a package structure for a solid-state imaging device (see, e.g., Japanese Patent Publication No. 2000-323692). Here, the transparent-substrate-directly-bonded package structure corresponds to the package structure in which the entire top surface of a semiconductor substrate having photodetector sections and the entire principal surface of a transparent substrate are bonded together using a transparent adhesive. One of the advantages of the transparent-substrate-directly-bonded package structure is that selection of an appropriate transparent adhesive can reduce the differences in refractive index among the transparent substrate, the transparent adhesive, and the semiconductor substrate. Reductions in the refractive index differences can reduce losses caused by light reflection at the interface between each adjacent pair of the transparent substrate, the transparent adhesive, and the semiconductor substrate. As a result, the sensitivity of a solid-state imaging device having a transparent-substrate-directly-bonded package structure can be improved.

### SUMMARY

In recent years, with each passing year, the trend has been to reduce the amount of signal charge generated in one pixel of a solid-state imaging device with a reduction in the light receiving area per pixel. To address the above problem, the structures described in above-described Japanese Patent Publication No. H02-2675 and Japanese Patent Publication No. 2000-323692 will further promote improvement in the sensitivity of solid-state imaging devices.

A semiconductor substrate is usually die-bonded to a package substrate, and electrodes disposed on the semiconductor substrate are usually wire-bonded to lead terminals disposed on the package substrate. When the transparent-substrate-directly-bonded structure is employed, the wire bonding is often performed after the bonding of a transparent sheet material to the semiconductor substrate in order to protect the semiconductor substrate from moisture and dust. However, with this procedure, when a transparent adhesive is applied to the semiconductor substrate, the transparent adhesive may flow out and adhere to a floating diffusion region of the semiconductor substrate or the electrodes. This may reduce the sensitivity of the solid-state imaging device and cause disconnections between the electrodes and corresponding wires. Thus, a simple combination of the structures described in Japanese Patent Publication No. H02-2675 and Japanese Patent Publication No. 2000-323692 cannot reduce the size and thickness of a corresponding solid-state imaging device while preventing the above-mentioned defects.

A solid-state imaging device according to an embodiment of the present disclosure can be equipped with a solid-state imaging element which can reduce defects and the size and thickness of the solid-state imaging device.

A solid-state imaging element according to an example of the present disclosure includes: a semiconductor substrate formed with a plurality of first photodetector sections; a plurality of first spacers formed over a first region of the semiconductor substrate in which the plurality of first photodetector sections are formed; a transparent adhesive filling gaps among the first spacers; and a transparent substrate fixed on top surfaces of the plurality of first spacers using the transparent adhesive.

With this structure, direct bonding of the transparent substrate onto the semiconductor substrate can reduce the thickness of the solid-state imaging element. Furthermore, appropriate selection of the shape and arrangement of the first spacers can prevent the transparent adhesive from flowing onto an electrode pad section of the semiconductor substrate when the semiconductor substrate and the transparent substrate are bonded together. This prevention can reduce the likelihood of disconnection etc. of the electrode pad section without providing spacers outside the first region (e.g., a valid pixel section) of the semiconductor substrate formed with the plurality of first photodetector sections to block flow of the transparent adhesive. This reduction can both reduce the planar size of the solid-state imaging element and improve the reliability thereof

Moreover, when the format size of an image captured by the solid-state imaging element is increased, a spacer may be provided on a region of the semiconductor substrate located outside the first region to block the flow of the transparent adhesive while the first spacers are provided as described above. Even with a reduction in the thickness of the transparent substrate, the provision of the spacer can prevent the transparent substrate from bending while reliably reducing the likelihood of disconnection of the electrode pad section.

In the solid-state imaging element, the transparent adhesive fills the gaps among the first spacers. Therefore, appropriate adjustment of the refractive indexes of the first spacers and the transparent adhesive can provide different advantages. For example, when the refractive index of the first spacers is greater than that of the transparent adhesive, this allows the first spacers to function as optical waveguides. Alternatively, when the refractive index of the first spacers is equal to that of the transparent adhesive, this allows greater flexibility in arranging the first spacers.

When color filters are provided, the first spacers may be formed only on pixels having a specific color.

A solid-state imaging device according to an example of the present disclosure includes the above-described solid-state imaging element, and a package substrate having a top surface on which the solid-state imaging element is mounted, and including a lead terminal connected to the electrode pad section.

This structure can reduce the size and thickness of the solid-state imaging element and defects. This reduction can reduce the size and thickness of the solid-state imaging device and improve the reliability thereof.

A method for fabricating a solid-state imaging element according to the present disclosure includes acts of: (a) forming a plurality of photodetector sections in a semiconductor substrate; (b) forming a plurality of spacers over a region of the semiconductor substrate in which the plurality of photodetector sections are formed, or on a region of a transparent substrate corresponding to the region of the semiconductor substrate in which the plurality of photodetector sections are formed; and (c) bonding a top surface of the semiconductor substrate and the transparent substrate together using a transparent adhesive with the spacers interposed between the top surface of the semiconductor substrate and the transparent substrate.

According to this method, the transparent substrate is bonded onto the valid pixel section of the semiconductor substrate with the spacers interposed therebetween. Therefore, while the thickness of the solid-state imaging element is reduced compared to a solid-state imaging element having a hollow structure, the arrangement and shape of the spacers can restrain the transparent adhesive from flowing onto the electrode pad section and allows the transparent adhesive to uniformly spread on the valid pixel section. This can reduce defects, and allows the planar size of the solid-state imaging element to be smaller than that of a solid-state imaging element configured so that spacers are formed outside the valid pixel section to block the flow of the transparent adhesive.

In the bonding act, the spacers may be formed on the semiconductor substrate or on the transparent substrate.

According to the solid-state imaging element of the example of the present disclosure, when the transparent substrate is directly bonded onto the semiconductor substrate, appropriate selection of the shape and arrangement of the spacers can prevent the transparent adhesive from flowing onto an unnecessary area, such as the electrode pad section, without forming a spacer on a region of the semiconductor substrate located outside the valid pixel section. This prevention can reduce the thickness and size of the solid-state imaging element and also reduce defects.

### BRIEF DESCRIPTION OF THE DRAWINGS

FIG. 1 is a plan view illustrating a solid-state imaging element according to a first embodiment of the present disclosure when viewed from above.

FIG. 2 is a cross-sectional view illustrating the solid-state imaging element according to the first embodiment and taken along the line II-II in FIG. 1.

FIG. 3 is an enlarged cross-sectional view illustrating an example of a valid pixel section of the solid-state imaging element according to the first embodiment.

FIG. 4 is a cross-sectional view illustrating a solid-state imaging device including the solid-state imaging element according to the first embodiment.

FIG. 5 is a plan view illustrating a solid-state imaging element according to a first variation of the first embodiment when viewed from above.

FIG. 6 is a plan view illustrating a solid-state imaging element according to a second variation of the first embodiment when viewed from above.

FIG. 7 is an enlarged cross-sectional view illustrating a valid pixel section of a solid-state imaging element according to a third variation of the first embodiment.

FIG. 8 is a plan view schematically illustrating an example of an arrangement of color filters when the solid-state imaging element according to the first embodiment is provided with the color filters.

FIG. 9 is a cross-sectional view taken along the line IX-IX illustrated in FIG. 8 when the solid-state imaging element according to the third variation of the first embodiment is provided with color filters.

FIG. 10 is a cross-sectional view illustrating a known solid-state imaging device having a hollow structure.

FIG. 11 is an enlarged cross-sectional view illustrating a valid pixel section of the known solid-state imaging device illustrated in FIG. 10.

FIG. 12 is an enlarged cross-sectional view illustrating a valid pixel section of the solid-state imaging device according to the first embodiment.

FIGS. 13A is an enlarged cross-sectional view illustrating the valid pixel section of the solid-state imaging element according to the first embodiment when the refractive index of spacers is greater than that of a transparent adhesive.

FIG. 13B is an enlarged cross-sectional view illustrating the valid pixel section when the refractive index of the spacers is equal to that of the transparent adhesive.

FIG. 13C is an enlarged cross-sectional view illustrating the valid pixel section when the refractive index of the spacers is less than that of the transparent adhesive.

FIG. 14 is a plan view illustrating a solid-state imaging element according to a second embodiment of the present disclosure.

FIGS. 15A-15C are cross-sectional views illustrating a method for fabricating a solid-state imaging element according to a reference example.

FIG. 16 is a cross-sectional view illustrating the solid-state imaging element according to the second embodiment and taken along the line XVI-XVI in FIG. 14.

FIG. 17 is a flow chart illustrating process steps in a method for fabricating a solid-state imaging device according to a fifth embodiment of the present disclosure.

FIGS. 18A-18D are cross-sectional views of a solid-state imaging element in essential ones of the process steps illustrated in FIG. 17.

FIGS. 19A-19C are cross-sectional views of the solid-state imaging element in other essential ones of the process steps illustrated in FIG. 17.

FIGS. 20A-20C are cross-sectional views illustrating process steps for making a solid-state imaging element in a method for fabricating a solid-state imaging device according to a sixth embodiment of the present disclosure.

FIGS. 21A-21C are cross-sectional views illustrating other process steps for making the solid-state imaging element in the method for fabricating a solid-state imaging device according to the sixth embodiment of the present disclosure.

### DETAILED DESCRIPTION

The best mode for carrying out the present disclosure will be described hereinafter in detail with reference to the drawings.

### Embodiment 1

—Structures of Solid-State Imaging Element and Solid-State Imaging Device—

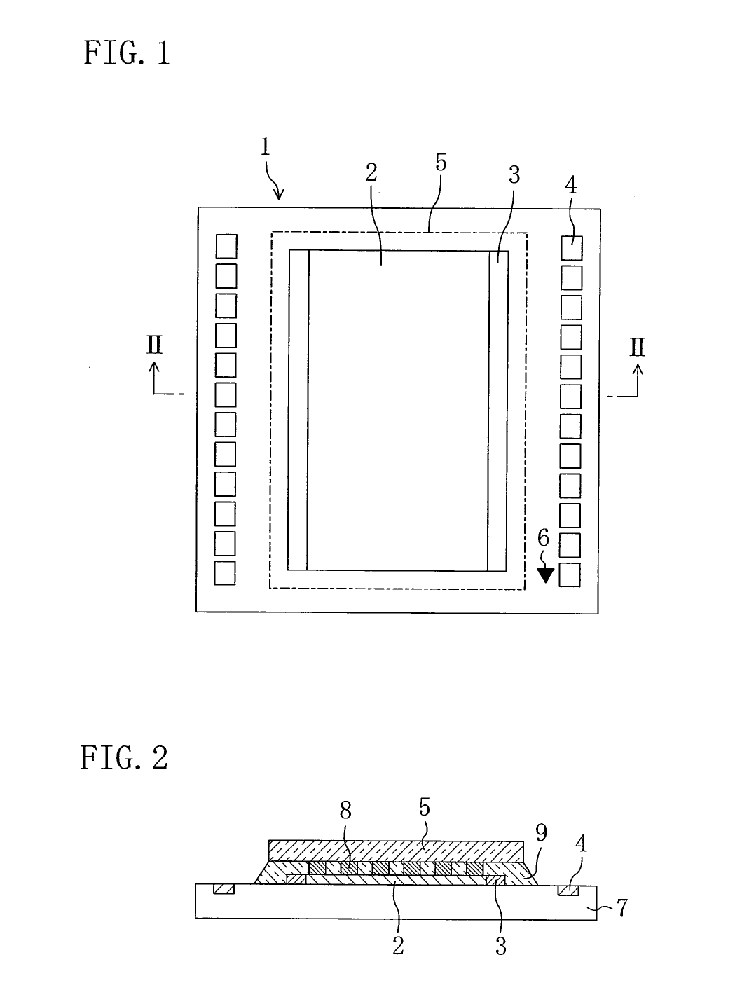

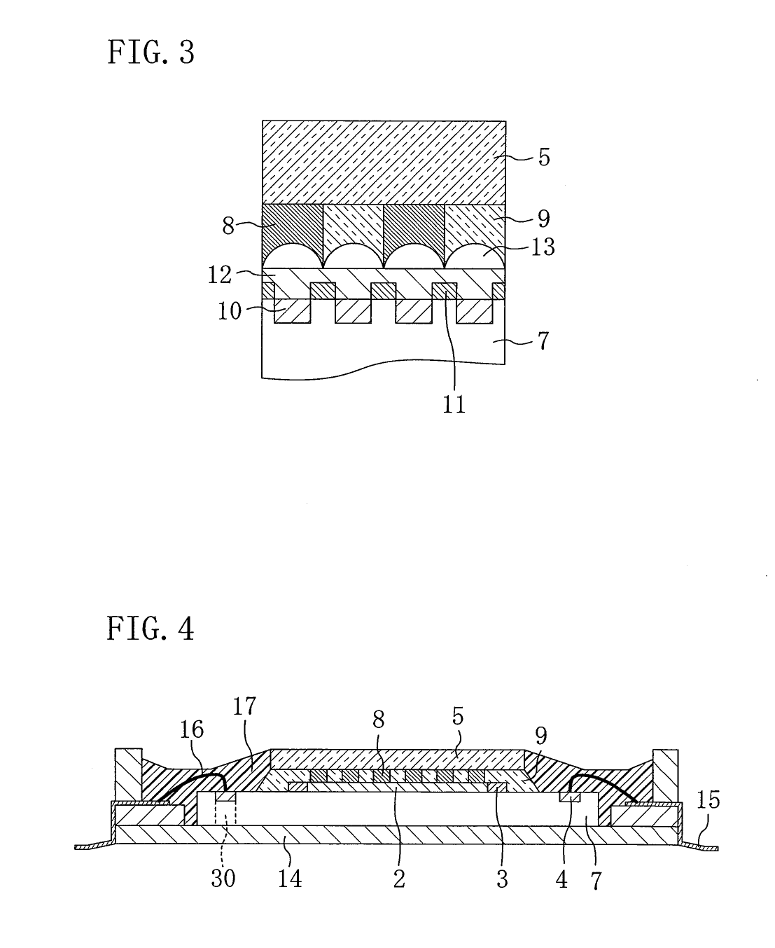

FIG. 1 is a plan view illustrating a solid-state imaging element 1 according to a first embodiment of the present disclosure when viewed from above. FIG. 2 is a cross-sectional view illustrating the solid-state imaging element according to this embodiment and taken along the line II-II in FIG. 1. FIG. 3 is an enlarged cross-sectional view illustrating an example of a valid pixel section of the solid-state imaging element according to this embodiment. FIG. 4 is a cross-sectional view illustrating a solid-state imaging device including the solid-state imaging element according to this embodiment. In the following description, for convenience, an object including a semiconductor substrate 7 formed with a valid pixel section 2 and an optical member, such as a transparent substrate (transparent member) 5, bonded to the semiconductor substrate 7 is denoted by a “solid-state imaging element.” A solid-state imaging element which is mounted on a package substrate 14 and is encapsulated with, e.g., an encapsulating resin is denoted by a “solid-state imaging device.”

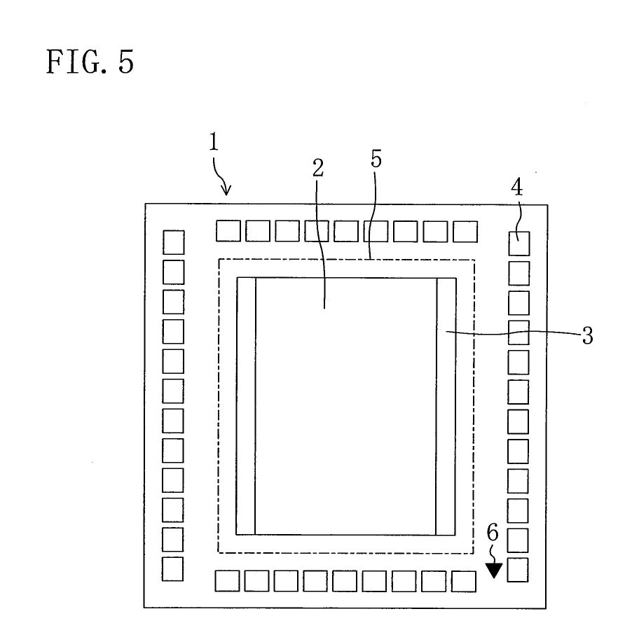

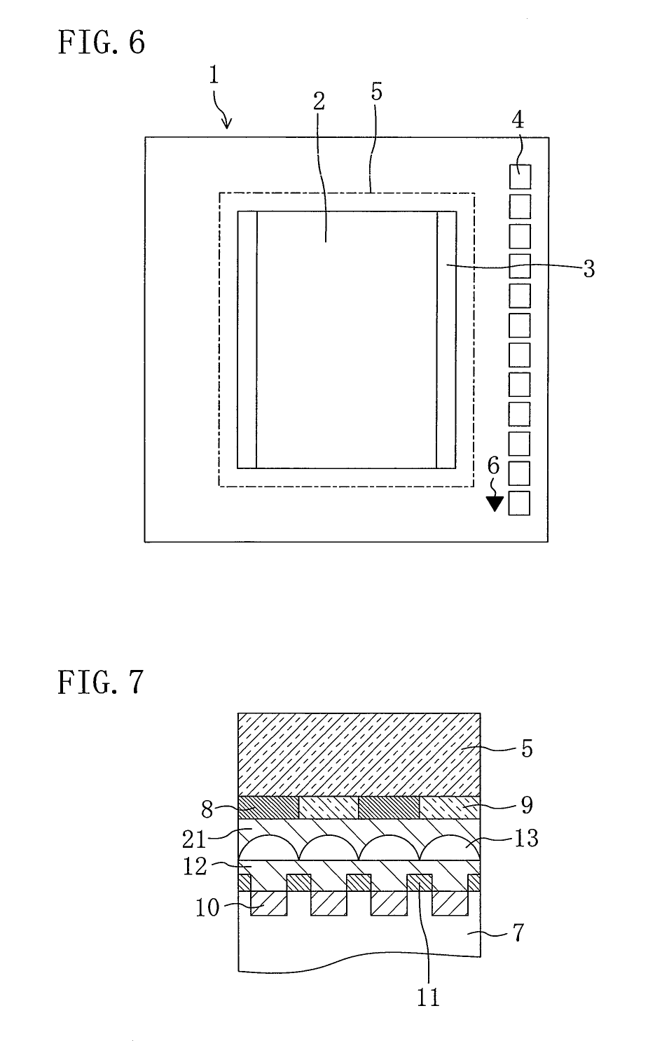

As illustrated in FIG. 1, the semiconductor substrate 7 for use in the solid-state imaging element 1 of this embodiment is sheet-like, and the planar shape of the semiconductor substrate 7 is, for example, quadrilateral. A transparent substrate 5 is shown by the dot-dash line in FIG. 1, and entirely covers the valid pixel section 2 and interconnect sections 3 on the semiconductor substrate 7 when viewed in a plane. The reference character 6 in FIG. 1 denotes a floating diffusion region. A center portion of a light-receiving face of the solid-state imaging element 1 is provided with the quadrilateral valid pixel section 2. The valid pixel section 2 includes a plurality of photodetector sections arranged in a matrix. A plurality of electrode pad sections 4 are arranged outside the valid pixel section 2, and aligned in a row along each of a pair of opposed ones of the four sides of the valid pixel section 2. The electrode pad sections 4 are provided to exchange signals with external circuits, for example, to send out a signal output from the valid pixel section 2. As illustrated in FIG. 5, the electrode pad sections 4 may be provided along the four sides of the semiconductor substrate 7. Alternatively, as illustrated in FIG. 6, the electrode pad sections 4 may be provided along only any one of the sides of the semiconductor substrate 7. Here, FIG. 5 is a plan view illustrating a solid-state imaging element according to a first variation of this embodiment. FIG. 6 is a plan view illustrating a solid-state imaging element according to a second variation of this embodiment.

As illustrated in FIG. 2, in the solid-state imaging element 1 according to this embodiment, the transparent substrate 5 is bonded onto the light receiving face of the semiconductor substrate 7 using a transparent adhesive 9. A plurality of spacers (first spacers) 8 are disposed between the valid pixel section 2 of the semiconductor substrate 7 and the transparent substrate 5. More specifically, the spacers 8 are disposed over the valid pixel section 2 and immediately below the transparent substrate 5. The spacers 8 correspond to one of the features of the solid-state imaging element 1 of this embodiment. Thus, the spacers 8 will be described below in detail.

As illustrated in FIG. 3, photodetector sections 10 which perform photoelectric conversion are formed in an upper part of a region of the semiconductor substrate 7 on which the valid pixel section 2 is formed. Transfer electrodes 11 etc. are formed on surface regions of the semiconductor substrate 7 adjacent to the photodetector sections 10. A planarization layer 12 covers the transfer electrodes 11, the semiconductor substrate 7, and the interconnect sections 3 to planarize steps. Microlenses 13 and the spacers 8 are sequentially formed on the planarization layer 12. The semiconductor substrate 7 and the transparent substrate 5 are bonded together using the transparent adhesive 9. In the example illustrated in FIG. 3, the transparent adhesive 9 is located directly on some of the microlenses 13 to fill the spaces between adjacent ones of the spacers 8.

Although an example in which the solid-state imaging element 1 is a charge coupled device (CCD) imaging element is illustrated in FIG. 3, the solid-state imaging element 1 may be a metal oxide semiconductor (MOS) imaging element.

Furthermore, as illustrated in FIG. 4, the solid-state imaging element 1 of this embodiment is mounted on a package substrate 14, and electrode pad sections 4 are electrically connected to lead terminals 15 placed on the package substrate 14 through wires 16. Thus, a solid-state imaging device is obtained. The lead terminals 15 are partially exposed to the outside of the package substrate 14, and form terminals for connection with external equipment. The exposed surfaces of the semiconductor substrate 7 and the wires 16 are encapsulated with an encapsulating resin 17.

The solid-state imaging element of this embodiment can be employed even while including a penetrating electrode 30 penetrating the semiconductor substrate 7 from the light receiving face of the semiconductor substrate 7 to the back face thereof (as illustrated by the dotted line in FIG. 4). In this case, a flip-chip connection may be employed in which the electrode pad sections 4 are connected to the lead terminals 15 on the package substrate 14 without providing the wires 16.

A material of the spacers 8 for use in the solid-state imaging device of this embodiment only needs to be a material which is transparent to at least incident light, and may be, for example, a photosensitive resin, such as an acrylic resin, a styrenic resin, a phenolic novolac resin, or a polyimide, a typical positive or negative photosensitive resin, or an organic resin, such as an urethane-based resin, an epoxy-based resin, a styrenic resin, or siloxane-based resin. The use of an organic resin permits the formation of the spacers 8 without problems even after an organic film (the planarization layer 12 etc.) with a low thermal resistance has been formed in order to form color filters, microlenses, etc. Alternatively, a material obtained by allowing a binder resin to contain a spheroidal, fiber-shaped, or irregular shaped filling material made of resin, glass, quartz, or any other material may be used as the material of the spacers 8. The filling material contained in the binder resin is approximately greater than 0% and less than or equal to 3000% (weight percent) of the binder resin. The refractive index or mechanical strength of the spacers 8 can be changed by changing the type and content of the filling material. For example, when a filling material with a high refractive index, such as titanium dioxide (TiO₂) or zirconium dioxide (ZrO₂), is contained in the binder resin, this can increase the refractive index of the spacers 8. Furthermore, when carbon, or an organic or inorganic pigment is contained in a resin, this can reduce the transmittance of visible light through the spacers 8. Even when the transmittance of visible light through the spacers 8 is lower than that through the transparent adhesive 9, the intensities or colors of signals output from pixels formed with the spacers 8 can be corrected. This can reduce degradation in image quality.

The transparent substrate 5 is made of an inorganic material (borosilicate glass, quartz glass, etc.), an organic material (an acrylic resin, a polycarbonate resin, an olefin resin, etc.), a hybrid of an inorganic material and an organic material, or any other material. Specifically, the transparent substrate 5 is preferably made of a material satisfying the following conditions: the transmittance of visible light through the material is high; the material can be shaped into a flat plate; and the material can be bonded to an object using a later-described transparent adhesive 9.

When an organic material is used as a material of the transparent substrate 5, and the shock resistance of the transparent substrate 5 is not adequate for some applications, a hybrid material to which an inorganic material is added as a filling material is more preferably used. When borosilicate glass is used as the material of the transparent substrate 5, the transparent substrate 5 is less likely to be damaged during handling of the transparent substrate 5 than when resins etc. are used thereas. The use of borosilicate glass can provide further advantages in terms of the solvent resistance and abrasion resistance of the transparent substrate 5 in fabrication of a solid-state imaging device, and cost. Also when quartz is used as the material of the transparent substrate 5, the transparent substrate 5 is less likely to be damaged during handling of the transparent substrate 5. The use of quartz can provide further advantages in terms of the solvent resistance and abrasion resistance of the transparent substrate 5 in fabrication of a solid-state imaging device.

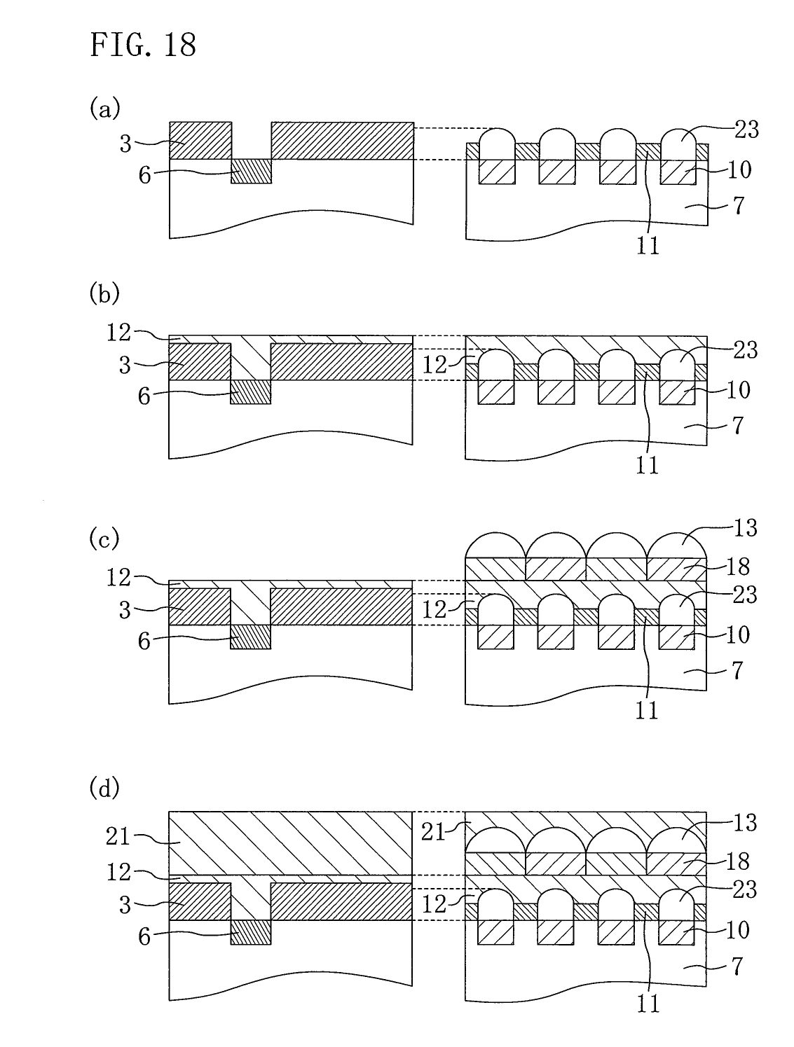

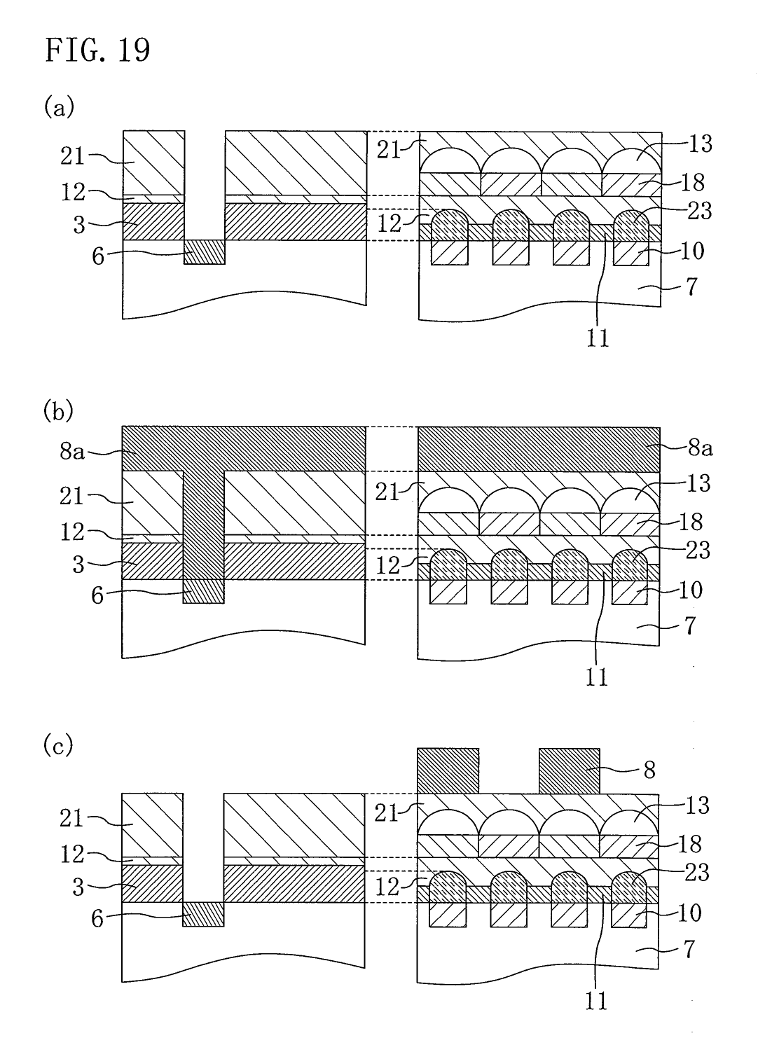

An example in which microlenses 13 of one type are disposed between the semiconductor substrate 7 and the transparent substrate 5 is illustrated in FIG. 3. However, microlenses of one or more types (so-called intralayer lenses) may be disposed between microlenses 13 directly below the transparent substrate 5 and the semiconductor substrate 7, and thus, light passing through two or more of the microlenses may enter a corresponding one of the photodetector sections (see FIGS. 18A-19C). In this case, the collection efficiency of incident light is improved, resulting in an improvement in the sensitivity of the photodetector sections.

In the example illustrated in FIG. 3, the planarization layer 12 is made of a material different from a material of the microlenses 13. However, the planarization layer 12 and the microlenses 13 may be made of the same material and integrally formed.

FIG. 7 is an enlarged cross-sectional view illustrating a valid pixel section of a solid-state imaging element according to a third variation of the first embodiment. As illustrated in FIG. 7, in the solid-state imaging element of this embodiment, an organic film 21 may cover microlenses 13 to protect the surface of the element. In this case, spacers 8 and a transparent adhesive 9 are located on the organic film 21. A material harder than the microlenses 13 is preferably used as a material of the organic film 21. Materials of the organic film 21 include, for example, an acrylic material, a fluorine-based material, or a silicone-based material. With the above-mentioned configuration, the solid-state imaging element can be less likely to be physically damaged, and in addition, appropriate selection of the refractive index of the organic film 21 can further reduce reflections of incident light. For example, when the refractive index of the organic film 21 is less than that of the microlenses 13, this can reduce reflections at the interfaces between the organic film 21 and the microlenses 13. Also when one or more microlenses (intralayer lenses) are formed between each of the microlenses 13 and a corresponding one of photodetector sections 10, this organic film 21 is effective.

In the solid-state imaging element of this embodiment, color filters 18 in one-to-one correspondence with the microlenses 13 may be provided on the planarization layer 12 and under the microlenses 13. This enables color imaging.

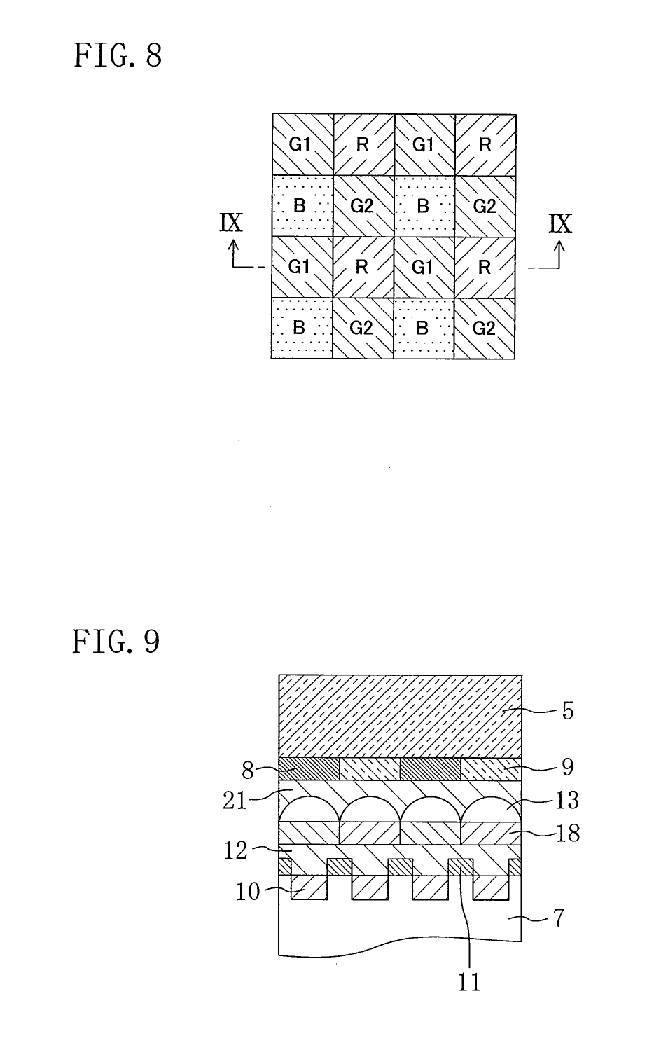

FIG. 8 is a plan view schematically illustrating an example of an arrangement of color filters when the solid-state imaging element of this embodiment is provided with the color filters. FIG. 9 is a cross-sectional view taken along the line IX-IX in FIG. 8 when the solid-state imaging element of the third variation of this embodiment is provided with color filters. In FIG. 8, for convenience, a valid pixel section is illustrated while being divided into pixels each including a photodetector section 10.

As illustrated in FIG. 8, when color filters are provided, the Bayer array of color filters with primary colors including a red (R), greens (G1, G2), and a blue (B), or any other arrangement is used as the arrangement of the color filters over the valid pixel section 2. In the example illustrated in FIG. 9, color filters 18 are disposed on a planarization layer 12 and immediately below microlenses 13, and are in one-to-one correspondence with the microlenses 13. When one or more microlenses (intralayer lenses) are formed between each of the microlenses 13 and a corresponding one of photodetector sections 10, the color filters 18 are disposed, for example, immediately below the uppermost microlenses.

Next, features and advantages of a solid-state imaging element and solid-state imaging device which are configured as described above will be described.

—Features and Advantages of Solid-State Imaging Element and Solid-State Imaging Device—

Features of the solid-state imaging device of this embodiment will be described in comparison with a known solid-state imaging device.

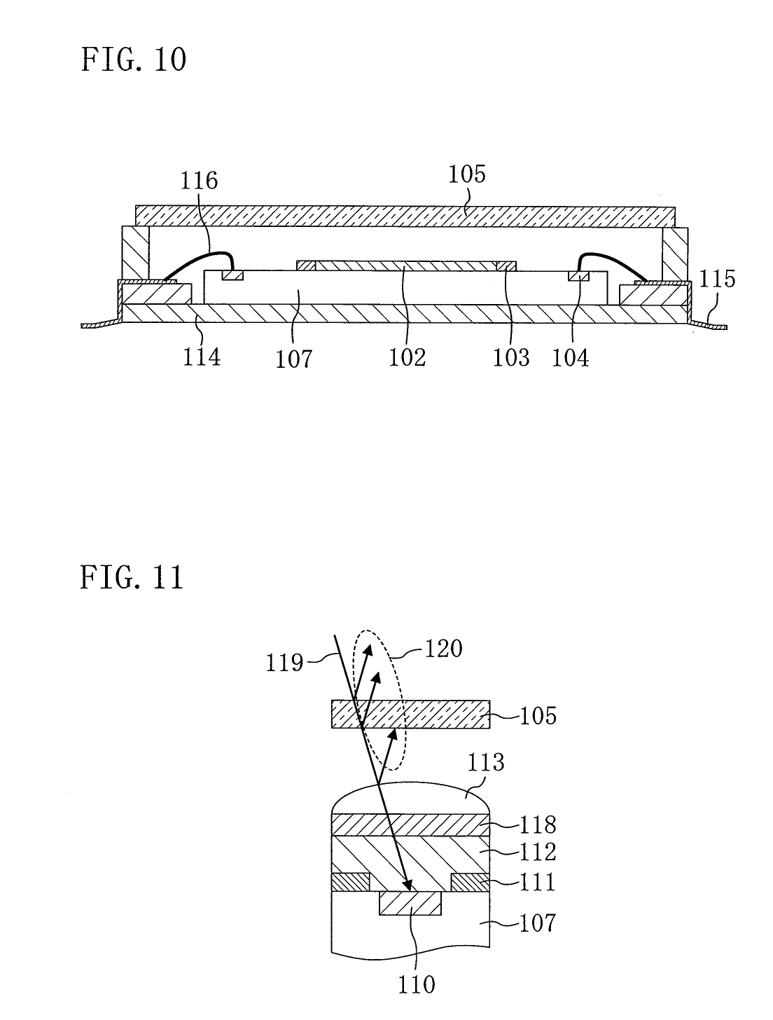

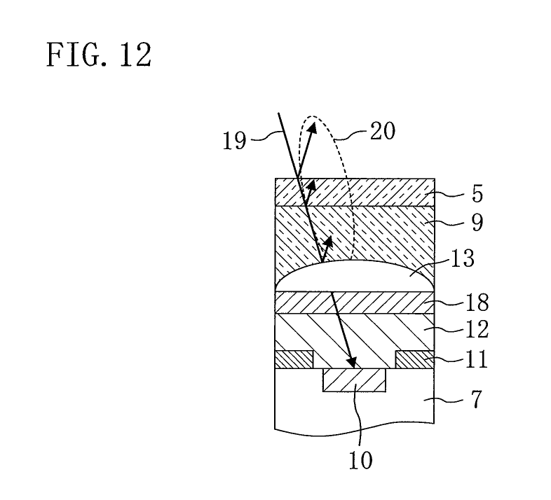

FIG. 10 is a cross-sectional view illustrating a known solid-state imaging device having a hollow structure. FIG. 11 is an enlarged cross-sectional view illustrating a valid pixel section of the known solid-state imaging device illustrated in FIG. 10. FIG. 12 is an enlarged cross-sectional view illustrating the valid pixel section of the solid-state imaging device according to the first embodiment.

As illustrated in FIG. 10, the known solid-state imaging device includes a semiconductor substrate 107 formed with a valid pixel section 102, interconnect sections 103, and electrode pad sections 104, a package substrate 114 on which the semiconductor substrate 107 is mounted and which includes lead terminals 115 connected to the electrode pad sections 104 through wires 116, and a transparent substrate 105 disposed above the semiconductor substrate 107. In FIG. 11, the reference characters 110, 111, 112, and 118 denote a photodetector section, transfer electrodes, a planarization layer, and a color filter, respectively. With this structure, incident light 119 which has entered a solid-state imaging element is reflected off the top and bottom surfaces of the transparent substrate 105 made of glass etc. and the upper surface of a microlens 113. This causes losses corresponding to reflected light rays 120. The reason for this is that the refractive index difference between the transparent substrate 105 or the microlens 113 and air is significant.

In contrast, in the solid-state imaging device of this embodiment, the transparent substrate 5 is bonded directly onto the valid pixel section 2 of the semiconductor substrate 7 using the transparent adhesive 9. A material having a greater refractive index than air is used as a material of the transparent adhesive 9. Therefore, in the solid-state imaging device of this embodiment, the refractive index differences between the transparent substrate 5 and the transparent adhesive 9 and between the microlenses 13 and the transparent adhesive 9 can be reduced. As illustrated in FIG. 12, this reduction can significantly reduce reflections of incident light 19 entering a solid-state imaging element off the bottom surface of the transparent substrate 5 and the upper surface of a microlens 13, compared to the known solid-state imaging device. This reduction can reduce light losses corresponding to reflected light rays 20. Furthermore, the thickness of a solid-state imaging element corresponding to the solid-state imaging device of this embodiment can be also reduced compared to the structure of the known solid-state imaging device. In addition, also for pixels formed with spacers 8, light reflections can be reduced compared to a known solid-state imaging element because the refractive index of the spacers 8 is also greater than that of air. Here, when the refractive index of the spacers 8 is less than that of a member located immediately below each of the spacers 8 (in the example illustrated in FIG. 12, the microlens 13), this can reduce reflections of light off the lower surfaces of the spacers 8.

Next, in the solid state imaging device of this embodiment, as illustrated in FIGS. 2 and 3, the spacers 8 are provided over the valid pixel section 2 and immediately below the transparent substrate 5. In fabricating a solid-state imaging element, the spacers 8 are formed on some of the microlenses 13, and then the transparent adhesive 9 is applied to the semiconductor substrate 7 or the transparent substrate 5 to bond the semiconductor substrate 7 and the transparent substrate 5 together. Therefore, provision of the spacers 8 can make it difficult for the transparent adhesive 9 to flow out of the valid pixel section 2. Thus, without spacers provided on a region of the semiconductor substrate 7 located outside the valid pixel section 2 to block flow of the transparent adhesive 9, appropriate selection of the height, arrangement, shape, etc., of the spacers 8 can prevent the transparent adhesive 9 from flowing onto the electrode pad sections 4. This prevention can prevent disconnections etc. of the electrode pad sections 4 and further eliminates the need for providing a region of the semiconductor substrate 7 which is located outside the valid pixel section 2 and on which spacers are to be formed. Thus, the element can be reduced in size. Furthermore, when the spacers 8 are appropriately spaced apart or appropriately shaped as described below, this allows the transparent adhesive 9 to uniformly spread out over the valid pixel section 2. Thus, problems, such as formation of air bubbles between adjacent ones of the spacers 8, can be also prevented. In this manner, the solid-state imaging element of this embodiment can reduce problems, such as disconnections of the electrode pad sections 4, while being reduced in size and thickness. Moreover, the top surfaces of the spacers 8 are flat and substantially parallel to the top surface of the semiconductor substrate 7. This can prevent the transparent substrate 5 from being inclined when it is bonded to the semiconductor substrate 7. This prevention can prevent degradation in image quality, such as luminance nonuniformity (luminance shading) caused when the transparent substrate 5 is bonded to the semiconductor substrate 7.

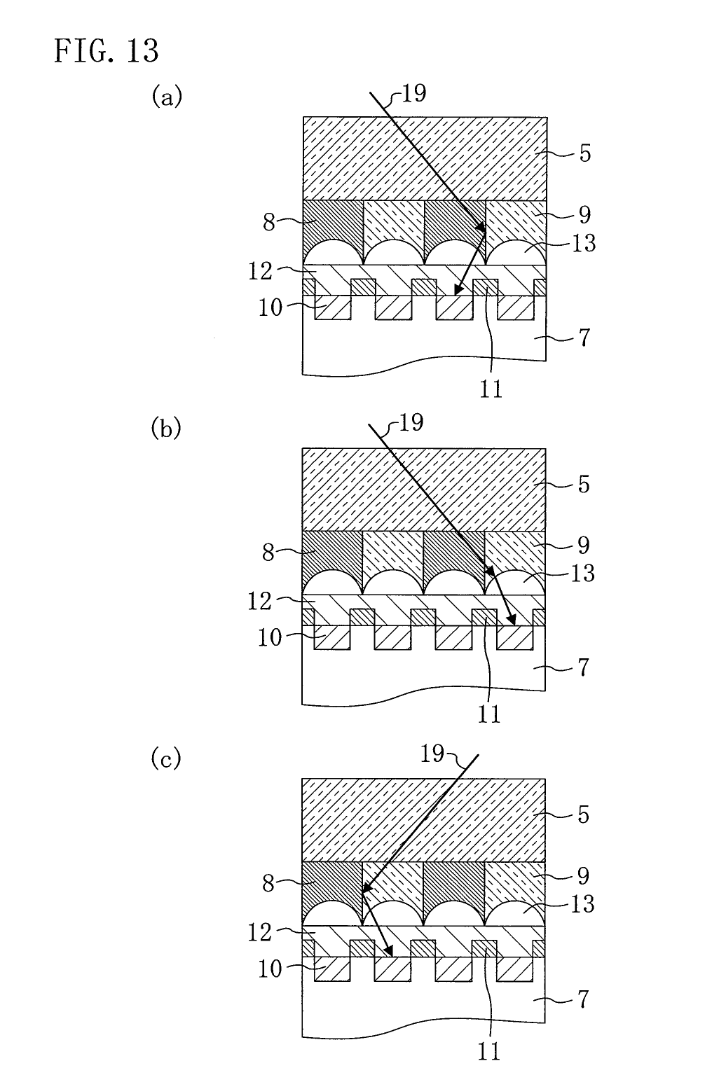

The refractive index of the spacers 8 may be identical with or different from that of the transparent adhesive 9. Advantages in both of the above cases will be described hereinafter with reference to FIGS. 13A-13C.

FIG. 13A is an enlarged cross-sectional view illustrating the valid pixel section of the solid-state imaging element of this embodiment when the refractive index of the spacers 8 is greater than that of the transparent adhesive 9. FIG. 13B is an enlarged cross-sectional view illustrating the valid pixel section when the refractive index of the spacers 8 is equal to that of the transparent adhesive 9. FIG. 13C is an enlarged cross-sectional view illustrating the valid pixel section when the refractive index of the spacers 8 is less than that of the transparent adhesive 9.

(1) Refractive Index of Spacers 8>Refractive Index of Transparent Adhesive 9

In this case, as illustrated in FIG. 13A, light obliquely entering one of the spacers 8 is refracted at the interface between the spacer 8 and the transparent adhesive 9 toward the spacer 8 and reflected with high efficiency. This allows the spacer 8 to function as an optical waveguide. This can selectively improve the sensitivity of photodetector sections 10 corresponding to pixels formed with the spacers 8. When the density of the spacers 8 functioning as optical waveguides and disposed on a peripheral part of the valid pixel section is high, and the density of the spacers 8 disposed on a center part of the valid pixel section is low, this can improve the sensitivity of the photodetector sections 10 corresponding to the peripheral part on which a smaller amount of light than the amount of light incident on the center part is incident to thereby equalize the brightness of an output image over the entire screen area. This will be described below.

(2) Refractive Index of Spacers 8=Refractive Index of Transparent Adhesive 9

In this case, as illustrated in FIG. 13B, light obliquely entering one of the spacers 8 propagates in a straight line without being refracted at the interface between the spacer 8 and the transparent adhesive 9, and enters one of the microlenses 13. With this structure, however the spacers 8 are disposed on the valid pixel section, the optical properties of the solid-state imaging device do not vary. This eliminates refraction of light at a side of the spacer 8. This elimination can prevent degradation in the optical properties. Furthermore, when spacers 8 are to be formed, they do not need to be precisely aligned. This allows greater flexibility in arranging the spacers 8. For example, each of the spacers 8 may be disposed astride a plurality of adjacent pixels. Alternatively, the spacer 8 may be formed on a part of the corresponding microlens 13.

(3) Refractive Index of Spacers 8<Refractive Index of Transparent Adhesive 9

In this case, light obliquely entering one of the spacers 8 is refracted at the interface between the spacer 8 and the transparent adhesive 9 toward the transparent adhesive 9. Here, for example, when spacers 8 are disposed on four pixels each sharing a common border with a pixel formed without a spacer 8, light entering the transparent adhesive 9 is refracted at the interface between the transparent adhesive 9 and the spacer 8 toward the transparent adhesive 9 as illustrated in FIG. 13C. This allows a portion of the transparent adhesive 9 surrounded by the spacers 8 on the four pixels to function as an optical waveguide. This can selectively improve the sensitivity of photodetector sections corresponding to desired pixels. When the transparent substrate 5 is bonded to the semiconductor substrate 7, the transparent adhesive 9 is less likely to spread over a region surrounded by the spacers 8. Thus, the transparent adhesive 9 is preferably applied to the semiconductor substrate 7 or the transparent substrate 5 by spray application etc.

Next, variations in arrangement of spacers 8 in use of color filters for the solid-state imaging element of this embodiment, and advantages in the use thereof will be described.

In the solid-state imaging element of this embodiment, as long as the locations where the spacers 8 are formed are within the valid pixel section, they are not limited in principle. The spacers 8 may be regularly disposed.

For example, in the solid-state imaging element illustrated in FIG. 9, the spacers 8 may be disposed only on pixels having one or more specific colors. Specifically, the spacers 8 may be disposed only on red pixels (R), only on one or both types of green pixels (G1 or G2, or both of G1 and G2), or only on blue pixels (B). Alternatively, some of the above-described arrangements may be combined. Signals output from the solid-state imaging element are often processed for each color of pixels. Thus, when the refractive index of the spacers 8 is different from that of the transparent adhesive 9, provision of the spacers 8 based on the colors of pixels can facilitate signal processing. This configuration is advantageous as described below in the section (2) of a third embodiment, in particular, when being used for a CCD solid-state imaging element.

Moreover, when, as described above, the refractive index of the spacers 8 is greater than that of the transparent adhesive 9, the formation of the spacers 8 only on green pixels can improve the sensitivity of the solid-state imaging element to green light, to which the visual sensitivity of the human eye is highest. This improvement can increase the pixel resolution.

Alternatively, when the refractive index of the spacers 8 is less than that of the transparent adhesive 9, the formation of the spacers 8, e.g., on red pixels and blue pixels can improve the sensitivity of photodetector sections corresponding to the green pixels surrounded by the spacers 8.

The colors of the color filters 18 may be complementary colors (cyan, magenta, and yellow) etc. other than the above-described primary colors. The spacers 8 may be formed only on pixels having any one color. Alternatively, the spacers 8 may be formed on pixels having a plurality of colors.

### Embodiment 2

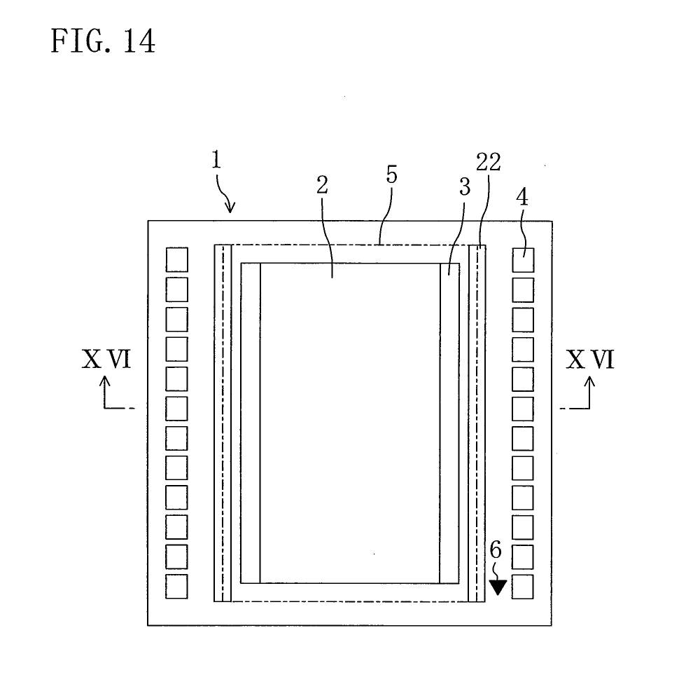

FIG. 14 is a plan view illustrating a solid-state imaging element according to a second embodiment of the present disclosure. As illustrated in FIG. 14, unlike the solid-state imaging element of the first embodiment illustrated in FIG. 1, the solid-state imaging element of this embodiment is configured so that spacers (third spacers) 22 are provided on a region of a semiconductor substrate 7 located outside a valid pixel section 2. Here, a configuration of the solid-state imaging element of this embodiment similar to that of the solid-state imaging element of the first embodiment will not be described, and features of this embodiment will be principally described.

In recent years, there has been a need to reduce the sizes of solid-state imaging elements. On the other hand, for imaging devices, such as single-lens reflex cameras, importance has been attached to image quality, and thus there has been a need to increase the format size of an image captured by a solid-state imaging element while reducing the thickness of such a solid-state imaging element. Methods for satisfying the needs include a method in which the thickness of a solid-state imaging element and the thickness of a solid-state imaging device including the solid-state imaging element are reduced by reducing the thickness of a transparent substrate 5 to approximately 100 μm.

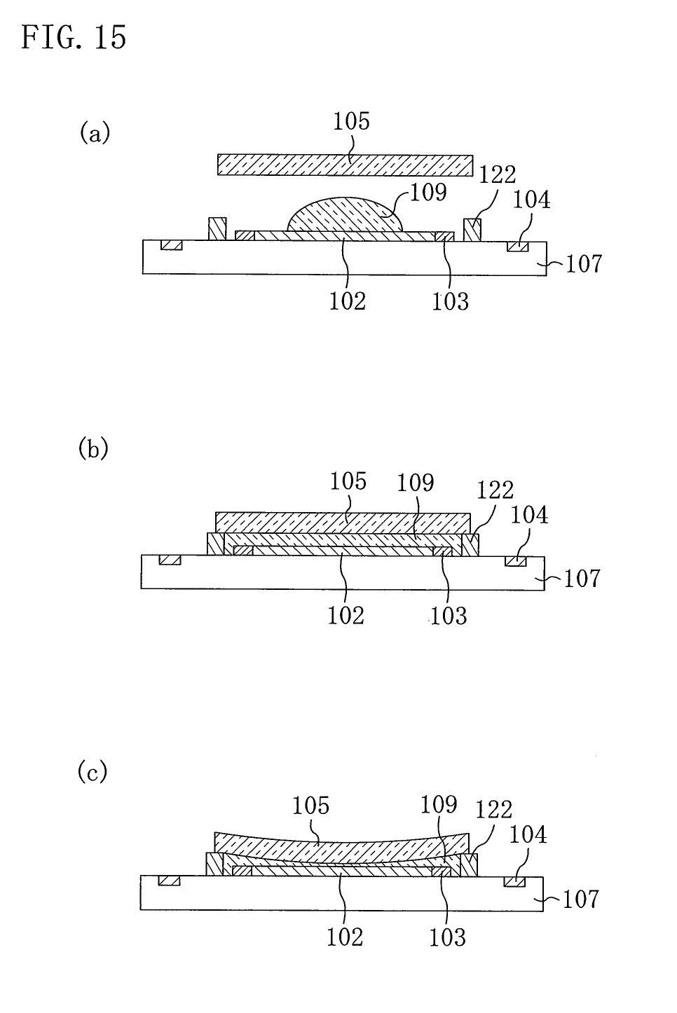

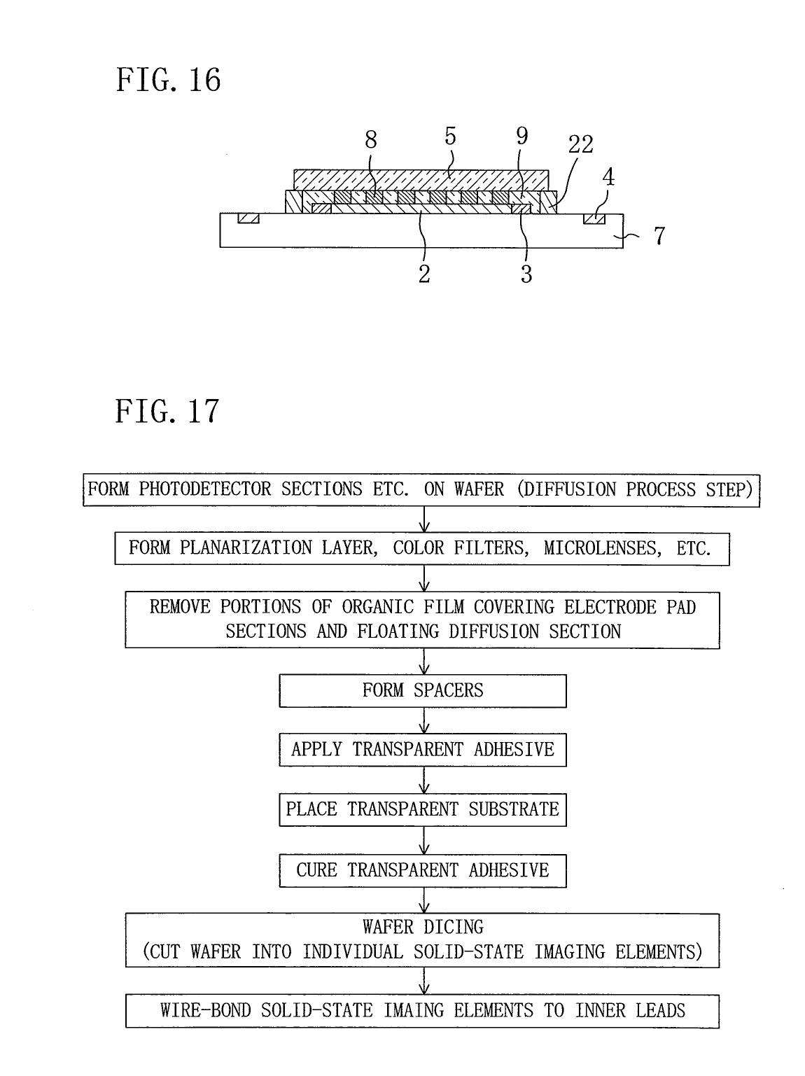

Here, FIG. 15A-15C are cross-sectional views illustrating a method for fabricating a solid-state imaging element according to a reference example. FIG. 16 is a cross-sectional view which illustrates the solid-state imaging element of the second embodiment illustrated in FIG. 14 and is taken along the line XVI-XVI therein.

According to the method of the reference example, as illustrated in FIGS. 15A and 15B, a semiconductor substrate 107 formed with a valid pixel section 102, interconnect sections 103, electrode pad sections 104, and spacers 122 is prepared, and then a transparent liquid adhesive 109 is applied onto the valid pixel section 102. In this state, a transparent substrate 105 is placed on the semiconductor substrate 107 and lightly pressed against the semiconductor substrate 107. The spacers 122 are located outside the valid pixel section 102 and provided, like partitions, along a pair of opposed sides of the valid pixel section 102. When the transparent substrate 105 is bonded to the semiconductor substrate 107, the provided spacers 122 block flow of the transparent adhesive 109. This can prevent the transparent adhesive 109 from flowing onto the electrode pad sections 104. However, as illustrated in FIG. 15C, when the distance between the spacers 122 is large, curing of the transparent adhesive 109 causes the transparent adhesive 109 to shrink. This shrinkage may cause the transparent substrate 105 to bend.

In contrast, in the solid-state imaging element of this embodiment, as illustrated in FIG. 16, spacers 22 are provided outside the valid pixel section 2 so that they are parallel to each other, and spacers 8 are provided within the planar region corresponding to the valid pixel section 2. This can reduce bending of the transparent substrate 5 in a process step of bonding the transparent substrate 5 to the semiconductor substrate 7 and thus reduce degradation in the optical properties of the solid-state imaging element etc. As such, in the solid-state imaging element of this embodiment, while the thickness of the solid-state imaging element is reduced, disconnections, degradation in the optical properties thereof, etc., can be reduced.

The thickness of the transparent substrate 5 is not limited to 100 μm. The structure of this embodiment is advantageous, in particular, when the thickness of the transparent substrate 5 is, for example, approximately greater than or equal to several tens of μm and less than or equal to 500 μm. Furthermore, the distance between the spacers 22 parallel to each other is, for example, identical with the pixel pitch (several μm) or an integral multiple of the pixel pitch. The length of one side of the semiconductor substrate 7 is, for example, approximately 10 mm to several tens of mm. In addition, the height of the spacers 8 is preferably approximately equal to that of the spacers 22, i.e., approximately several μm to 50 μm.

### Embodiment 3

Patterns in which spacers 8 are formed immediately below a transparent substrate 5 will be described as a third embodiment of the present disclosure. The patterns are illustrated in FIGS. 3 and 7.

The formation patterns of the spacers 8 provided immediately below the transparent substrate 5 include, for example, the following patterns.

(1) Patterns Configured so that the Density of the Spacers 8 on a Center Part of a Valid Pixel Section 2 is High While the Density thereof on a Peripheral Part of the Valid Pixel Section 2 is Low

Use of such a pattern for a solid-state imaging element having a large chip size can reduce bending of the transparent substrate 5 and thus reduce degradation in the optical properties of the solid-state imaging element as described in the second embodiment. When the spacers 8 are not provided, the degree of bending of a part of the transparent substrate 5 corresponding to the center part of the valid pixel section 2 is greater than that of a part of the transparent substrate 5 corresponding to the peripheral part thereof. However, with the above-described patterns, the total area of the spacers 8 located on the center part of the valid pixel section 2 is greater than that of the spacers 8 located on the peripheral part thereof. This can increase the load bearing capability of the solid-state imaging device and thus reduce the bending of the transparent substrate 5.

Here, the density of the spacers 8 denotes the number of the spacers 8 per unit area.

(2) Patterns Configured so that the Spacers 8 are Uniformly Formed on the Entire Valid Pixel Section 2

Such patterns include, e.g., a pattern configured so that, as described in the first embodiment, spacers 8 are provided on pixels of one or more specific colors. Use of this pattern can improve the sensitivity of photodetector sections corresponding to desired pixels as described above. In particular, for CCD solid-state imaging elements, reading of signals cannot be controlled on a pixel-by-pixel basis, and thus signals are corrected on a color-by-color basis. Therefore, even with such a CCD solid-state imaging element, when spacers 8 are regularly formed within a planar region corresponding to the valid pixel section 2, the influence of the spacers 8 on the optical properties of the CCD solid-state imaging element etc. can be corrected by signal processing.

Furthermore, provision of appropriately spaced spacers 8 allows a transparent adhesive 9 to uniformly spread over the entire valid pixel section 2.

(3) Patterns Configured so that the Density of the Spacers 8 on a Center Part of a Valid Pixel Section 2 is Low While the Density thereof on a Peripheral Part of the Valid Pixel Section 2 is High

When, as described in the first embodiment, spacers 8 or portions of a transparent adhesive 9 surrounded by the spacers 8 function as optical waveguides, use of such a pattern can improve the sensitivity of photodetector sections corresponding to the peripheral part of the valid pixel section 2 on which a smaller amount of light than the amount of light incident on the center part of the valid pixel section 2 is incident. This improvement can improve image quality. When the transparent substrate 5 is placed on a semiconductor substrate 7 and pressed against the semiconductor substrate 7, the transparent adhesive 9 rapidly spreads over the valid pixel section 2 because the density of the spacers 8 located on the center part of the valid pixel section 2 is low.

(4) Patterns Configured so that the Distances Between Adjacent Ones of the Spacers 8 Located on the Peripheral Part of the Valid pixel section 2 are Smaller than those Between Adjacent Ones of the Spacers 8 Located on the Center Part thereof

With such a pattern, flow of a transparent adhesive 9 is blocked and stops on the peripheral part of the valid pixel section 2 in a bonding process step without providing such spacers 22 as illustrated in FIG. 16 outside the valid pixel section 2. In particular, a combination of this pattern and the above-described pattern (3) allows the transparent adhesive 9 to rapidly spread over the valid pixel section 2 in the bonding process step, and can prevent the transparent adhesive 9 from protruding outwardly of the valid pixel section 2 (toward electrode pad sections 4 etc.).

In the above-described patterns (1) and (3), the density of the spacers 8 may be abruptly (nonlinearly) or gradually (linearly) changed from the center of the valid pixel section 2 toward the periphery thereof.

When the spacers 8 do not affect the properties of a solid-state imaging element and a solid-state imaging device (as illustrated in FIG. 13B), the spacers 8 may be formed at random locations.

The cross sections of spacers 8 taken in a plane horizontal to the principal surface of the semiconductor substrate 7 (hereinafter referred to as “the horizontal cross sections”) may be circular or polygonal. In this manner, when the transparent substrate 5 is placed on the semiconductor substrate 7 and pressed against the semiconductor substrate 7, the spacers 8 are less likely to block the flow of the transparent adhesive 9. Thus, the transparent substrate 5 can be tightly bonded onto the semiconductor substrate 7. This advantage is significant particularly when the horizontal cross sections of the spacers 8 are circular.

### Embodiment 4

A solid-state imaging device according to a fourth embodiment of the present disclosure includes an OB (optical black) area adjacent to a valid pixel section 2, and is configured so that spacers made of a light-blocking material are disposed, as light-blocking films, over the OB area.

The configuration of pixels located in the OB area is similar to that of pixels located in the valid pixel section 2 except for spacers 8. Specifically, pixels in the OB area each include a photodetector section 10, a transfer electrode 11, a portion of a planarization layer 12, and a microlens 13 (see FIGS. 3, 7, and 9). Noise (dark current) is removed by differencing a signal output from one of the pixels in the valid pixel section 2 and a signal output from one of the pixels in the OB area.

In the solid-state imaging element of this embodiment, light-blocking spacers (second spacers) cover microlenses 13 over the entire OB area. The light-blocking spacers are made of a material obtained by mixing carbon, or an organic or inorganic pigment into any one of the resins described above as a material of the spacers 8. The light-blocking spacers may be provided alone. Alternatively, the light-blocking spacers may be provided in combination with the spacers 8 on the valid pixel section 2.

For a solid-state imaging element, interconnects made of a metal are often formed, as light-blocking films, on an OB area (see FIGS. 18A-18C, etc.). In this case, the thickness of the interconnects needs to be increased. This causes a difference in level between the valid pixel section and the interconnects at the time of manufacture of the solid-state imaging element. To address this problem, a planarization layer 12 etc. are formed over a substrate to compensate for the level difference.

In contrast, for the solid-state imaging element of this embodiment, the light-blocking spacers protect the OB area from light. This eliminates the need for providing an interconnect on the OB area, and can further reduce the thickness of the interconnects. Therefore, the solid-state imaging element of this embodiment and the solid-state imaging device equipped with the same can be drastically reduced in thickness.

### Embodiment 5

A method for fabricating a solid-state imaging device and a process for forming spacers 8 in the fabrication method will be described in a fifth embodiment of the present disclosure.

FIG. 17 is a flow chart illustrating process steps in a method for fabricating a solid-state imaging device according to the fifth embodiment of the present disclosure. Furthermore, FIGS. 18A-19C are cross-sectional views of a solid-state imaging element in essential ones of the process steps illustrated in FIG. 17. In this embodiment, a method for fabricating the solid-state imaging element of the first embodiment which is provided with color filters 18, intralayer lenses 23, and an organic film 21 will be described as an example. In each of FIGS. 18A-19C, the left diagram illustrates a cross section of the solid-state imaging element passing through an interconnect section 3 and a floating diffusion region 6, and the right diagram illustrates a cross section thereof passing through photodetector sections 10, microlenses 13, etc.

First, as illustrated in FIG. 18A, photodetector sections 10, a floating diffusion region 6, etc., are formed in an upper part of a semiconductor substrate 7 at the wafer level in a known diffusion process step. Subsequently, transfer electrodes 11 of a predetermined shape are formed on the semiconductor substrate 7, and then intralayer lenses 23 are formed on the photodetector sections 10 of the semiconductor substrate 7. In this case, while the semiconductor substrate 7 is rotated, a material of the intralayer lenses 23 is applied to the semiconductor substrate 7, and then the intralayer lenses 23 each having a convex upper surface are formed by a photolithography process etc. The material of the intralayer lenses 23 may be a transparent resin or an inorganic material, such as SiN. Next, an interconnect section 3 is formed on a predetermined region of the semiconductor substrate 7, and is the first layer formed on the semiconductor substrate 7. Electrode pad sections 4 may be formed simultaneously with the formation of the interconnect section 3. Here, the top surface of the interconnect section 3 is above the top of each of the intralayer lenses 23. However, for the solid-state imaging element of the fourth embodiment, the height of the interconnect section 3 can be equal to or less than that of the intralayer lens 23. Furthermore, in forming the solid-state imaging element without any intralayer lens 23 as illustrated in FIG. 9, this process step is not required.

Next, as illustrated in FIG. 18B, while the semiconductor substrate 7 is rotated, a transparent resin etc. is applied to the semiconductor substrate 7. In this manner, a planarization layer 12 is formed by a photolithography process etc. to cover the intralayer lenses 23 and the interconnect section 3. Thus, the upper surface of the substrate, i.e., the upper surface of an unfinished solid-state imaging element, is planarized.

Next, as illustrated in FIG. 18C, color filters 18 are formed on portions of the planarization layer 12 located over a valid pixel section 2 by a known process. Then, microlenses 13 are formed on the color filters 18.

Next, as illustrated in FIG. 18D, an organic film 21 is formed to cover the microlenses 13 over the valid pixel section 2 and the planarization layer 12 on the interconnect section 3.

Next, as illustrated in FIG. 19A, respective portions of the organic film 21, the planarization layer 12, etc., formed on the floating diffusion region 6 are removed, e.g., by etching. In this case, like the respective portions of the organic film 21 and the planarization layer 12 formed on the floating diffusion region 6, respective portions thereof formed on the electrode pad sections 4 are also removed, e.g., by etching.

Thereafter, as illustrated in FIG. 19B, a material of spacers 8 is applied to the entire substrate area, thereby forming a spacer material film 8a. In this case, while the semiconductor substrate 7 is rotated, the material is applied to the semiconductor substrate 7 (spin coating).

Next, as illustrated in FIG. 19C, the spacer material film 8a is subjected to a photolithography process etc., thereby curing portions of the spacer material film 8a serving as the spacers 8 and separating the other portions thereof from the above-described portions thereof In this process step, the spacers 8 are formed on the valid pixel section 2.

Here, the material of the spacers 8 may be a material which is transparent to at least incident light, and may be, for example, a photosensitive resin, such as an acrylic resin, a styrenic resin, a phenolic novolac resin, or a polyimide, a typical positive or negative photosensitive resin, or an organic resin, such as an urethane-based resin, an epoxy-based resin, a styrenic resin, or siloxane-based resin. Alternatively, a material obtained by allowing a binder resin to contain a spheroidal, fiber-shaped, or irregular shaped filling material made of resin, glass, quartz, or any other material may be used as the material of the spacers 8. The filling material is approximately greater than 0% and less than or equal to 3000% (weight percent) of the binder resin. The refractive index or mechanical strength of the spacers 8 can be changed by changing the type and content of the filling material. For example, when a filling material with a high refractive index, such as titanium dioxide (TiO₂) or zirconium dioxide (ZrO₂), is contained in the binder resin, this can increase the refractive index of the spacers 8. Furthermore, the transmittance of visible light through the spacers 8 may be reduced by allowing the binder resin to contain carbon, or an organic or inorganic pigment.

Moreover, the thickness of the spacers 8 can be arbitrarily selected. As long as the thickness of the spacer material film 8a is approximately 1-50 μm, the spacer material film 8a can be formed in a single step by spin coating. When the spacer material film 8a is to be thicker than the above thickness, the spin coating is repeated one or more times. Furthermore, use of spin coating allows the top surface of the semiconductor substrate 7 and the top surface of an applied film to be substantially parallel to each other. The spacers 8 can be formed by leaving predetermined portions of the spacer material film 8a and removing the other portions thereof. When the spacer material film 8a is thick, it can be formed by die coating.

When the spacers 8 are made of a photosensitive resin, the photosensitive resin is formed, then portions of the photosensitive resin serving as the spacers 8 are cured by a photolithography process, and unnecessary portions thereof are separated from the above-described portions thereof For example, the rotational speed of the semiconductor substrate 7 during spin coating is approximately 1000-3000 rpm, the pre-bake temperature in the photolithography process is approximately 80-100° C., the exposure time for the photolithography process is approximately 100-1000 msec, and an alkaline or organic developer is used as a developer for the photolithography process.

Alternatively, when the spacers 8 are made of an etchable resin, a film of the resin is formed, and then a resist mask is formed using a usual lithography process to cover portions of the resin film serving as the spacers 8 and expose the other portions thereof. Next, while the portions of the resin film serving as the spacers 8 are left, the other unnecessary portions thereof are removed by etching.

Thereafter, a transparent adhesive 9 is applied onto regions of the semiconductor substrate 7 corresponding to the photodetector sections 10. For example, an epoxy-based adhesive which can be cured at temperatures of approximately 100-150° C., a silicone-based adhesive which can be cured at temperatures ranging approximately from room temperature to 150° C., or any other adhesive is used as the transparent adhesive 9. For example, a dispense process is used as a process for applying the transparent adhesive 9 onto the regions of the semiconductor substrate 7. Here, the transparent adhesive 9 denotes an adhesive which is transparent after being cured.

Next, the transparent adhesive 9 is applied onto the semiconductor substrate 7, and then a transparent substrate 5 is bonded to the semiconductor substrate 7. In this bonding process, the transparent substrate 5 is initially placed on the semiconductor substrate 7 onto which the transparent adhesive 9 is applied. Then, while the transparent adhesive 9 is in fluid condition, the transparent substrate 5 is pressed against the top surfaces of the spacers 8 to come into contact with them. While or after the transparent substrate 5 is pressed, it is shifted horizontally to adjust the horizontal location and inclination of the transparent substrate 5. In terms of moisture resistance and dirt resistance, the semiconductor substrate 7 is preferably encapsulated by a package substrate 14, the transparent substrate 5, and the transparent adhesive 9. Therefore, in the process step of applying the transparent adhesive 9, the amount and location of the applied transparent adhesive 9 are previously adjusted so that when the transparent substrate 5 is bonded to the semiconductor substrate 7, the semiconductor substrate 7 is encapsulated with the transparent adhesive 9 wrapped around the spacers 8. Caution must be taken to prevent the wrapped transparent adhesive 9 from reaching a region located on the semiconductor substrate 7 and corresponding to the floating diffusion region 6. Thereafter, the transparent adhesive 9 is cured while the transparent substrate 5 is in contact with the top surfaces of the spacers 8.

Thereafter, the semiconductor substrate 7 is singulated into chips. The semiconductor substrate 7 is mounted on the package substrate 14. Next, the electrode pad sections 4 and lead terminals 15 are wire-bonded together, thereby forming a solid-state imaging device.

As described above, in the solid-state imaging element described in the first embodiment, the formed spacers 8 can prevent the semiconductor substrate 7 and the transparent substrate 5 from bending due to shrinkage of these substrates caused by curing of the transparent adhesive 9 when the transparent substrate 5 is bonded to the semiconductor substrate 7. Furthermore, the formed spacers 8 can prevent the transparent adhesive 9 applied to regions located on the semiconductor substrate 7 and corresponding to the photodetector sections 10 from flowing onto the region located on the semiconductor substrate 7 and corresponding to the floating diffusion region 6. Thus, the sensitivity of the solid-state imaging device can be increased by approximately several to 10%.

Furthermore, the transparent substrate 5 is bonded to the semiconductor substrate 7 while being pressed against the top surfaces of the spacers 8 to come into contact with them. Therefore, the distance between the semiconductor substrate 7 and the transparent substrate 5, i.e., the thickness of the transparent adhesive 9, is defined by the height of the spacers 8. Thus, the transparent adhesive 9 can also have a desired thickness. When the top surface of the semiconductor substrate 7 is used as a reference, the top surfaces of the spacers 8 are higher than the tops of the microlenses 13. Specifically, a gap exists between the transparent substrate 5 and the uppermost surface of a member formed on the semiconductor substrate 7, such as the microlenses 13. Here, the spacers 8 function to prevent the microlenses 13 from being crushed. Thus, when the transparent substrate 5 is positioned along its height, the transparent substrate 5 is less likely to crush the microlenses 13 etc. at the locations where the spacers 8 are not provided. Furthermore, when the transparent substrate 5 is positioned along its height as described above, the transparent substrate 5 is less likely to crush the microlenses 13 etc. also at the locations where the spacers 8 are provided.

Furthermore, when the transparent substrate 5 is bonded to the semiconductor substrate 7 while being brought into contact with the top surfaces of the spacers 8, the transparent substrate 5 can be bonded to the semiconductor substrate 7 so that these substrates are substantially parallel to each other. The reason for this is that the top surfaces of the spacers 8 are substantially parallel to the top surface of the semiconductor substrate 7. In particular, for the solid-state imaging element of the first embodiment, the spacers 8 are located on substantially the entire surface area of the valid pixel section 2. Thus, in the solid-state imaging element of the first embodiment, the transparent substrate 5 can be bonded to the semiconductor substrate 7 so that these substrates are parallel to each other. Consequently, degradation in image quality, such as luminance nonuniformity (luminance shading) caused when the transparent substrate 5 is bonded to the semiconductor substrate 7, can be prevented.

The fabrication method of this embodiment can reduce product-to-product variations in the height of the spacers 8 because the spacers 8 are formed in a wafer level process (a process before the semiconductor substrate 7 is divided into chips).

Use of a directly bonded structure in which the transparent substrate 5 and the semiconductor substrate 7 are directly bonded together through the transparent adhesive 9 can reduce the size and thickness of the entire solid-state imaging device. Furthermore, since the microlenses 13 are not exposed to air after the bonding of the transparent substrate 5, this can prevent degradation in the shape and transparency of the microlenses 13 and variations in the refractive index thereof due to changes in the ambient environment, such as changes in the humidity of the atmosphere. This advantage is significant particularly when the microlenses 13 are made of a transparent resin.

In order to form the spacer material film 8a, die coating or evaporation may be used instead of the process in which the material of the spacer material film 8a is applied to the semiconductor substrate 7 by spin coating. Alternatively, a dry process, such as sputtering, may be used. Furthermore, when a photosensitive resin is used as a material of the spacers 8, the spacers 8 can be also patterned by photolithography, nano-imprinting, etc. Unlike use of a process in which the spacers 8 are patterned by etching, use of these processes eliminates the need for forming an etching mask. This can simplify process steps for fabricating the solid-state imaging device. When the spacers 8 are made of a material other than a photosensitive resin, they can be also patterned by a lift-off process, a dry etching process, an inkjet process, etc. Use of a dry etching process allows a wider choice of materials for the spacers 8 than use of a photosensitive resin as a material thereof.

For the solid-state imaging element illustrated in FIG. 13C, when the semiconductor substrate 7 and the transparent substrate 5 are bonded together, the transparent adhesive 9 is less likely to flow through regions surrounded by the spacers 8. Thus, the transparent adhesive 9 is preferably applied to the surface area of the semiconductor substrate 7 by spray application.

### Embodiment 6

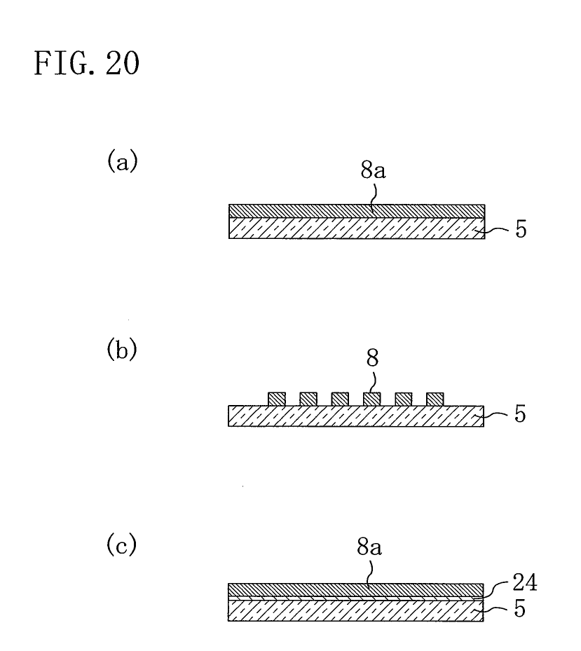

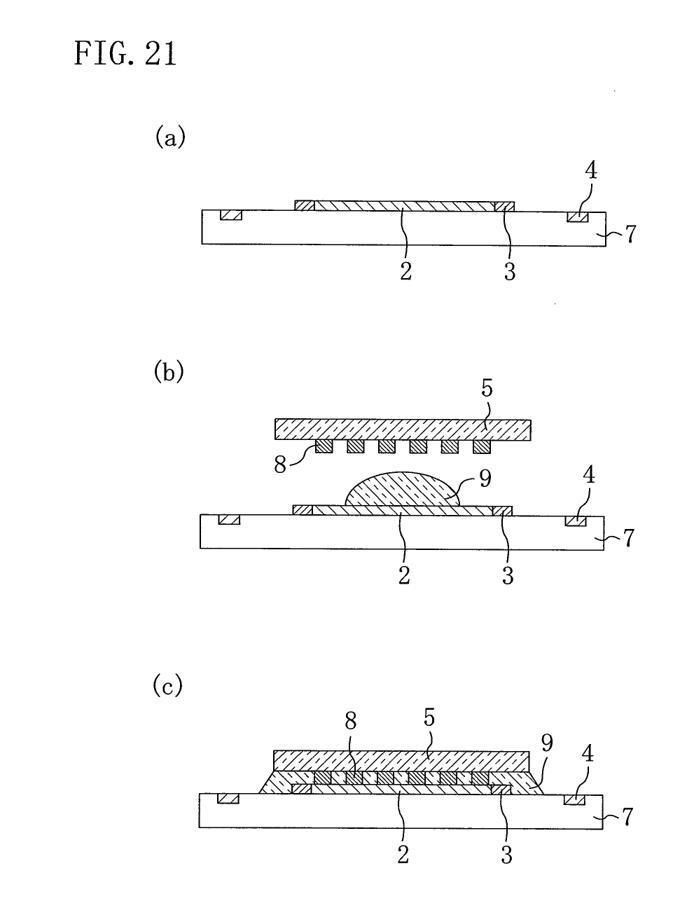

FIGS. 20A-21C are cross-sectional views illustrating process steps for making a solid-state imaging element in a method for fabricating a solid-state imaging device according to a sixth embodiment of the present disclosure. A procedure for formation of spacers 8 in the method of this embodiment differs from that in the method of the fifth embodiment.

First, as illustrated in FIG. 20A, a resin material which will partially form spacers 8 is applied onto a transparent substrate 5 by spin coating, thereby forming a spacer material film 8a. Here, as long as the thickness of the spacer material film 8a is, for example, approximately 1-50 μm, the spacer material film 8a can be formed in a single step by spin coating. The spacers 8 are made of, for example, a resin. For example, a photosensitive resin, such as an acrylic resin, a styrenic resin, a phenolic novolac resin, or a polyimide, a typical positive or negative photosensitive resin, or an organic resin, such as an urethane-based resin, an epoxy-based resin, a styrenic resin, or siloxane-based resin, can be used as a material of the spacers 8.

Next, as illustrated in FIG. 20B, the spacer material film 8a is partially removed by lithography etc., and thus desired portions of the spacer material film 8a are left. In this manner, spacers 8 are formed on the transparent substrate 5. As illustrated in FIG. 20C, when the spacers 8 are to be formed, an underlying layer 24 may be formed on the transparent substrate 5, and then the spacer material film 8a may be formed on the underlying layer 24. The purpose for this is, for example, to improve the adhesion between the spacers 8 and the transparent substrate 5. Materials of the underlying layer 24 include, for example, an organic material, such as HMDS (1,1,1,3,3,3-hexamethyldisilazane) or acryl, silicon dioxide (SiO₂), etc. A wet process, such as spraying, spin coating, or die coating, may be used as a process for forming the underlying layer 24. Alternatively, a dry process, such as sputtering, evaporation, or chemical vapor deposition (CVD), may be used. Furthermore, before the formation of the spacers 8, the transparent substrate 5 may be previously cut into sizes corresponding to individual solid-state imaging elements. Alternatively, the spacers 8 may be formed on a large transparent substrate 5, and then the transparent substrate 5 may be cut into sizes corresponding to individual solid-state imaging elements by a dicing process etc.

Next, as illustrated in FIGS. 21A and 21B, a transparent adhesive 9 is applied onto a valid pixel section 2 of a semiconductor substrate 7. Thereafter, the transparent substrate 5 is placed on the valid pixel section 2 of the semiconductor substrate 7 while the surface of the transparent substrate 5 on which the spacers 8 are formed faces toward the semiconductor substrate 7.

Then, as illustrated in FIG. 21C, the transparent adhesive 9 is cured while the transparent substrate 5 is lightly pressed against the semiconductor substrate 7. Light, such as ultraviolet light or visible light, may be applied to the transparent adhesive 9 in order to cure the transparent adhesive 9. Alternatively, a temperature of approximately 100-200° C. may be applied to the transparent adhesive 9. Furthermore, alternatively, both light and heat may be applied to the transparent adhesive 9.

When the spacers 8 and the transparent adhesive 9 have an equal refractive index, a material of the spacers 8 may be identical with that of the transparent adhesive 9.

When the transparent substrate 5 on which the spacers 8 are formed is to be bonded to the semiconductor substrate 7, the uppermost surface of the valid pixel section 2 of the semiconductor substrate 7 (the surface of the valid pixel section 2 to be bonded to the spacers 8) is preferably flat.

Even with the above-described method, when the transparent substrate 5 is bonded to the semiconductor substrate 7, the presence of the spacers 8 between the transparent substrate 5 and the semiconductor substrate 7 can prevent the transparent substrate 5 from bending due to shrinkage of these substrates caused by curing of the transparent adhesive 9. In addition, the presence of the spacers 8 can prevent the transparent adhesive 9 applied onto regions of the semiconductor substrate 7 corresponding to photodetector sections 10 thereof from flowing onto a region thereof corresponding to a floating diffusion region 6 thereof. Thus, the respective sensitivities of the solid-state imaging element and a solid-state imaging device equipped with the solid-state imaging element can be also increased by approximately several to 10%.

Furthermore, the transparent substrate 5 is bonded to the semiconductor substrate 7 while the distal end faces of the spacers 8 are pressed against the semiconductor substrate 7 to come into contact with the top surface of a substrate (a portion of an unfinished solid-state imaging element including the semiconductor substrate 7). Therefore, the distance between the substrate and the transparent substrate 5, i.e., the thickness of the transparent adhesive 9, is defined by the height of the spacers 8. Thus, when the spacers 8 have a desired height, the transparent adhesive 9 can also have a desired thickness.

When the uppermost surface of the valid pixel section 2 of the semiconductor substrate 7 is flat, and the transparent substrate 5 and the semiconductor substrate 7 are bonded together with the semiconductor substrate 7 brought into contact with the distal end faces of the spacers 8, the transparent substrate 5 and the semiconductor substrate 7 can be bonded together so that the transparent substrate 5 is substantially parallel to the surface of the semiconductor substrate 7. In particular, for the solid-state imaging element of the first embodiment, the spacers 8 are located on substantially the entire surface area of the valid pixel section 2. Thus, the transparent substrate 5 can be relatively precisely bonded onto the semiconductor substrate 7 so that these substrates are substantially parallel to each other. Consequently, degradation in image quality, such as luminance nonuniformity (luminance shading) caused when the transparent substrate 5 is bonded to the semiconductor substrate 7, can be prevented.

Use of a directly bonded structure in which the transparent substrate 5 and the semiconductor substrate 7 are directly bonded together through the transparent adhesive 9 can reduce the size and thickness of the solid-state imaging element and, eventually, those of the entire solid-state imaging device. Furthermore, degradation in the shape and transparency of the microlenses 13 and variations in the refractive index thereof due to changes in the ambient environment, such as changes in the humidity of the atmosphere, can be prevented.

In order to form the spacer material film 8a, die coating or evaporation may be used instead of the process in which the material of the spacer material film 8a is applied to the semiconductor substrate 7 by spin coating. Alternatively, a dry process, such as sputtering, may be used. Furthermore, when a photosensitive resin is used as a material of the spacers 8, the spacers 8 can be also patterned by photolithography, nano-imprinting, etc. When the spacers 8 are made of a material other than a photosensitive resin, they may be also patterned by a lift-off process, a dry etching process, an inkjet process, etc.

As described above, a solid-state imaging element and solid-state imaging device according to an example of the present disclosure can be utilized for, e.g., various imaging devices, such as digital cameras, video cameras, etc.

The foregoing description illustrates and describes the present disclosure. Additionally, the disclosure shows and describes only the preferred embodiments of the disclosure, but, as mentioned above, it is to be understood that it is capable of changes or modifications within the scope of the concept as expressed herein, commensurate with the above teachings and/or skill or knowledge of the relevant art. The described hereinabove are further intended to explain best modes known of practicing the invention and to enable others skilled in the art to utilize the disclosure in such, or other embodiments and with the various modifications required by the particular applications or uses disclosed herein. Accordingly, the description is not intended to limit the invention to the form disclosed herein. Also it is intended that the appended claims be construed to include alternative embodiments.

What is claimed is:

1. A solid-state imaging element comprising:
a semiconductor substrate including a plurality of first photodetector sections;
a plurality of first spacers formed over a first region of the semiconductor substrate in which the plurality of first photodetector sections are formed;
a transparent adhesive filling gaps among the first spacers; and
a transparent substrate fixed on top surfaces of the plurality of first spacers using the transparent adhesive.

2. The solid-state imaging element of claim 1, wherein
a number of the first spacers on a center portion of the first region per unit area is greater than a number of the first spacers on a peripheral portion of the first region per unit area.

3. The solid-state imaging element of claim 1, wherein
a number of the first spacers on a center portion of the first region per unit area is less than a number of the first spacers on a peripheral portion of the first region per unit area.

4. The solid-state imaging element of claim 1, wherein
a distance between an adjacent pair of the first spacers provided on a peripheral portion of the first region is less than a distance between an adjacent pair of the first spacers provided on a region of the semiconductor substrate other than the peripheral portion of the first region.

5. The solid-state imaging element of claim 1, wherein
a refractive index of the first spacers is substantially equal to a refractive index of the transparent adhesive.

6. The solid-state imaging element of claim 1, wherein
a refractive index of the first spacers is different from a refractive index of the transparent adhesive.

7. The solid-state imaging element of claim 1, wherein
a refractive index of the first spacers is less than a refractive index of a layer which is formed over the semiconductor substrate and immediately below the first spacers.

8. The solid-state imaging element of claim 1, wherein
the first spacers contain a filling material.

9. The solid-state imaging element of claim 1, wherein
the first spacers are made of an organic resin.

10. The solid-state imaging element of claim 1 further comprising
microlenses provided over the first region of the semiconductor substrate so as to be in one-to-one correspondence with the plurality of first photodetector sections, and located immediately below or under the first spacers.

11. The solid-state imaging element of claim 10 further comprising
color filters disposed under the microlenses and being in one-to-one correspondence with the microlenses.

12. The solid-state imaging element of claim 11, wherein
the first spacers are in one-to-one correspondence with the microlenses, and
the first spacers are disposed over one or more of the color filters having a specific color.

13. The solid-state imaging element of claim 1, wherein
the semiconductor substrate includes a second region having a second photodetector section and being adjacent to the first region, and
a second spacer made of a light-blocking material is formed immediately below the transparent substrate to cover the second region.

14. The solid-state imaging element of claim 13, wherein
the first region is a valid pixel section.

15. The solid-state imaging element of claim 13, wherein
the second region is an optical black area.

16. The solid-state imaging element of claim 1, wherein
cross sections of the first spacers taken in a plane horizontal to a principal surface of the semiconductor substrate are circular or polygonal.

17. The solid-state imaging element of claim 1 further comprising:
an electrode pad section formed in a region of the semiconductor substrate located outside the first region; and
a third spacer formed on a third region of the semiconductor substrate located between the electrode pad section and the first region and disposed along a side of the first region.

18. A solid-state imaging device comprising:
a solid-state imaging element including:
a semiconductor substrate formed with a plurality of photodetector sections and an electrode pad section;
a plurality of spacers formed over a region of the semiconductor substrate in which the plurality of photodetector sections are formed;
a transparent adhesive filling gaps among the spacers; and
a transparent substrate fixed on top surfaces of the spacers using the transparent adhesive; and
a package substrate having a top surface on which the solid-state imaging element is mounted, and including a lead terminal connected to the electrode pad section.

19. A method for fabricating a solid-state imaging element, the method comprising acts of:
(a) forming a plurality of photodetector sections in a semiconductor substrate;
(b) forming a plurality of spacers over a region of the semiconductor substrate in which the plurality of photodetector sections are formed, or on a region of a transparent substrate corresponding to the region of the semiconductor substrate in which the plurality of photodetector sections are formed; and
(c) bonding a top surface of the semiconductor substrate and the transparent substrate together using a transparent adhesive with the spacers interposed between the top surface of the semiconductor substrate and the transparent substrate.

20. The method of claim 19, wherein
in the act (b), the spacers are formed over the region of the semiconductor substrate in which the plurality of photodetector sections are formed.

21. The method of claim 20, wherein
in the act (b), a photosensitive material is applied onto the semiconductor substrate, and then the spacers are formed using photolithography by curing predetermined portions of the photosensitive material.

22. The method of claim 20, wherein
in the act (b), a non-photosensitive material is formed to cover the semiconductor substrate, and then portions of the non-photosensitive material other than predetermined portions of the non-photosensitive material are removed, thereby forming the spacers made of the non-photosensitive material.
